(19) United States
(12) Patent Application Publication
(10) Pub. No.: US 2003/0041794 A1
(43) Pub. Date: Mar. 6, 2003

(54) Cooling down system of the surfscan apparatus

(75) Inventors: Chi-Pin Hu, Hsin-Chu (TW); Jui-Yen Liu, Chia-I (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/945,628

(22) Filed: Sep. 5, 2001

(51) Int. Cl. C30B 28/10

(52) U.S. Cl. 117/13

(57) ABSTRACT

A cooling system comprises: a plurality of inhaling devices that are installed in the circuit-board room and connected with a plurality of ventholes the air between the plurality of circuit boards in the circuit-board room; a power generator is connected with the plurality of inhaling devices to supply the power into the cooling system, wherein the power generator can not affect the operation of the surfscan apparatus.

### BACKGROUND OF THE INVENTION

1. Field of the Invention

The present invention generally relates to a surfscan apparatus in semiconductor manufacturing, and more particularly to a cooling down system of the surfscan apparatus.

2. Description of the Prior Art

The need for reduced cost per wafer unit processed drives the semiconductor industry continuously to search for ways to increase wafer yield and reduce production cycle time. It is well recognized that overall semiconductor wafer fabrication system productivity increases are achieved by ensuring a constant supply of wafers at each tool, thus, the transaction capability of the factory material handling system affecting the number of wafer carriers circulating in a factory. As the wafer size has increased, the handling of wafers has become more limited to factory automation, instead of manual handling, to accommodate the increase in size and weight of wafer pods. In other words, the transaction of an interface apparatus transferring a wafer or a wafer cassette into a processing or metrology tool becomes more and more important and complicated. Semiconductor wafer handling and processing have always required extreme care to avoid contamination due to ambient and process-born particles. Such contamination lowers process yields, thus making the manufacture of integrated circuits more expensive and time consuming.

Accurate wafer surface topography measurement is one of the greatest challenges facing the semiconductor industry as it advances toward the 0.13-micron node. Surface topography variations can create film thickness non-uniformity following chemical mechanical planarization (CMP) processes as well as make end-point detection more difficult. Film non-uniformity can lead to resistivity variations, resulting in reduced device performance or complete device failure. Therefore, the development of the surfscan apparatus is necessary to scan the wafer surface, so as to avoid the contamination and measure the topography of the wafer surface.

Today, the TENCOR-SP1 is a main surfscan apparatus; the front of the TENCOR-SP1 100 is shown in FIG.1. The TENCOR-SP1 100 has a circuit-board room 110, there are a plurality of circuit boards 120, such as DSP (Digital Signal Process) board or analog board or CPU ( Central Processing Unit ) board, in the circuit-board room 110.

Nevertheless, the space in the circuit-board room 110 is very narrow, and that plurality of circuit boards 120 are densely placed in the circuit-board room 110, so that the air is difficult to convect in the space of the circuit-board room 110. Furthermore, the TENCOR-SP1 100 is continuously operated almost every day. Therefore, the plurality of circuit boards 120 in the circuit-board room 110 are heated to very high temperatures with the resulting in a reduced life-time of the plurality of circuit board 120 that is prone to crashes and down time.

In accordance with the above description, a new and improved system for cooling down the surfscan apparatus of TENCOR-SP1 is therefore necessary, so as to raise the stability and life-time of the surfscan apparatus. SUMMARY OF THE INVENTION

In accordance with the present invention, a system is provided for cooling down the surfscan apparatus that substantially overcomes the drawbacks of the above mentioned problems that arise from the conventional apparatus.

Accordingly, it is a main object of the present invention to provide a system for cooling the surfscan apparatus. This invention can use a cooling system in the circuit-board room to avoid over heating circuit boards in the circuit-board room, so as to increase the life-time of the circuit boards. Furthermore, this invention can also prevent the circuit boards crash or go down as a result of over heating. Therefore, this invention can reduce the maintainable cost of the conventional apparatus, whereby the present invention can correspond to economic effect. Hence, the present invention is appropriate for deep sub-micron technology in providing semiconductor apparatus.

In accordance with the present invention, a new system for cooling the surfscan apparatus is disclosed. First of all, a surfscan apparatus having a circuit-board room therein that is used to place a plurality of circuit boards is provided. Continued wherein the circuit-board room has a plurality of ventholes and a hood plate to cover and close the circuit-board room. A cooling system comprises a plurality of intake cooling devices, such as a fan. The plurality of intake cooling devices are installed in the circuit-board room and connected the circuit-board room with the surrounding of the surfscan apparatus to convect the air between the plurality of circuit boards in the circuit-board room, whereby heat in the circuit-board room can be transmitted to the surrounding of the surfscan apparatus by way of the plurality of ventholes. A power generator is connected with the plurality of intake/exhaust cooling devices to supply the power into the cooling system, wherein the power generator can not affect the operation of the surfscan apparatus.

The temperature in the circuit-board room rises to a specific temperature during the operation of the surfscan apparatus. At this moment, the power generator is switched on to start the plurality of intake devices. Then the plurality of inhaling devices will work to cool down the temperature in the circuit-board room, so as to avoid over heating circuit boards and result in a crash or down time. Furthermore, the plurality of inhaling devices can convect air in the circuit-board room to emit the heat into the environment via the ventholes or inhale the cooling air into the circuit-board room from the environment to keep a temperature that is suitable for operation of the circuit boards in the circuit-board room, so as to raise the stability of the operation and life-time of the surfscan apparatus. Therefore, this invention can reduce the maintainable cost of the surfscan apparatus.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows cross-sectional views illustrative of the surfscan apparatus of TENCOR-SP1 without the cooling system; and

FIG. 2A to FIG. 2C show cross-sectional views illustrative of the surfscan apparatus of TENCOR-SP1 with a cooling system in accordance with the first embodiment of the present invention.

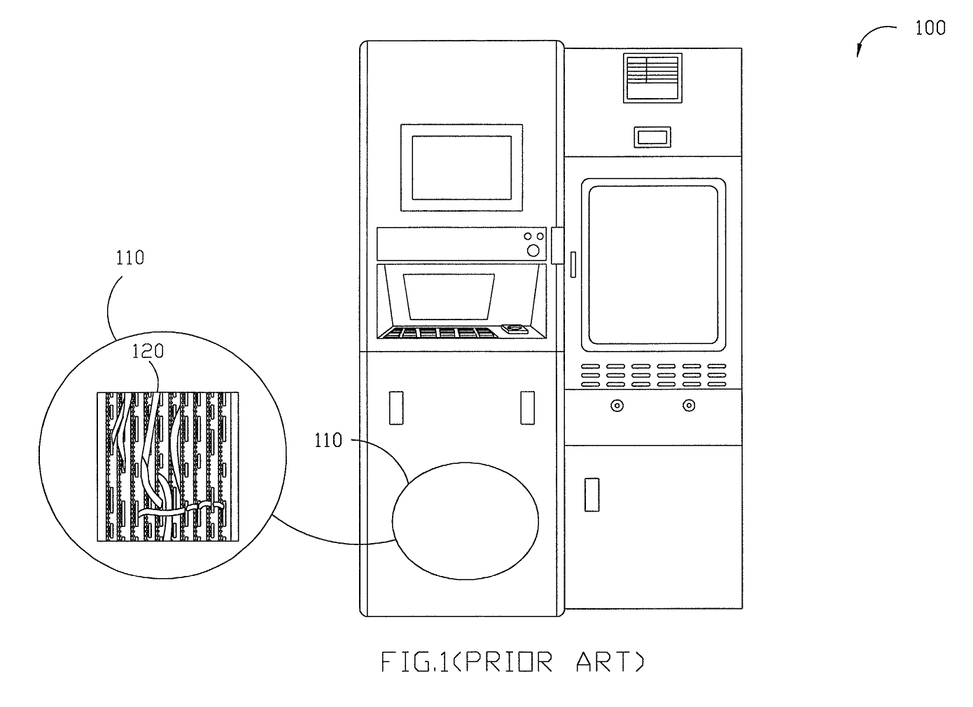

### DESCRIPTION OF THE PREFERRED EMBODIMENT

A preferred embodiment of the present invention will now be described in greater detail. Nevertheless, it should be recognized that the present invention can be practiced in a wide range of other embodiments besides those explicitly described, and the scope of the present invention is expressly not limited except as specified in the accompanying claims.

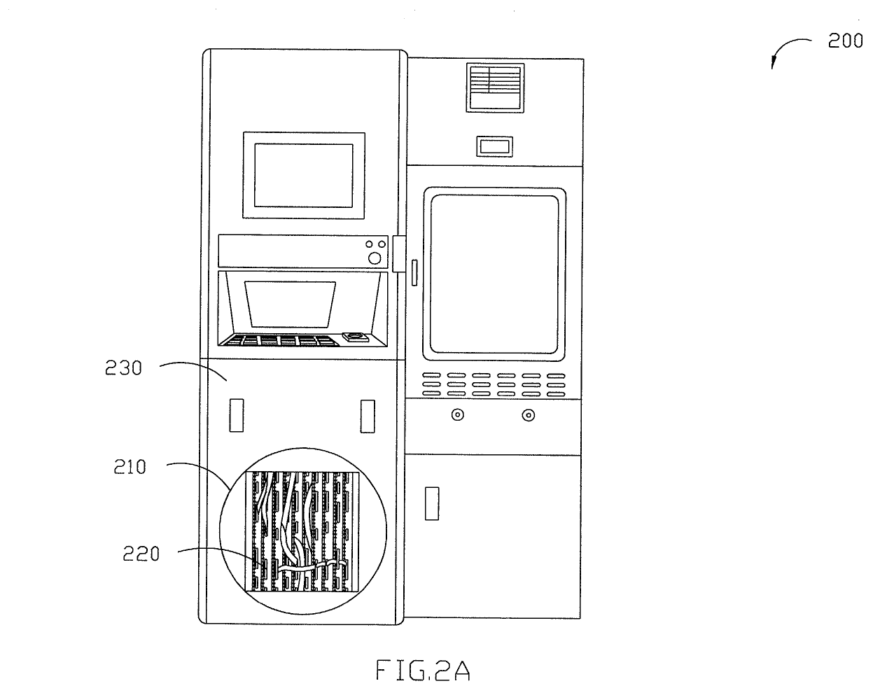

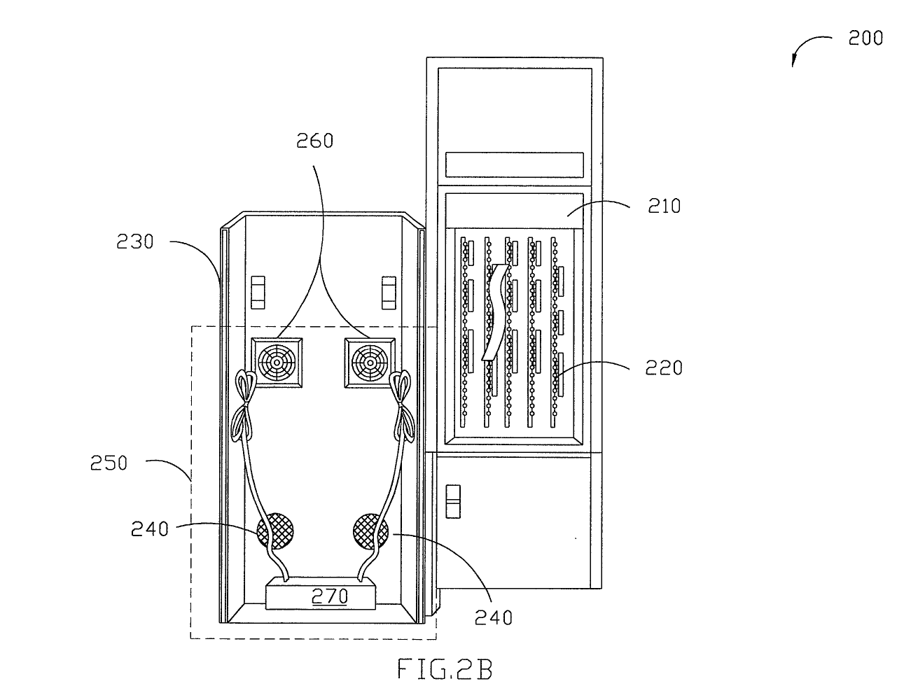

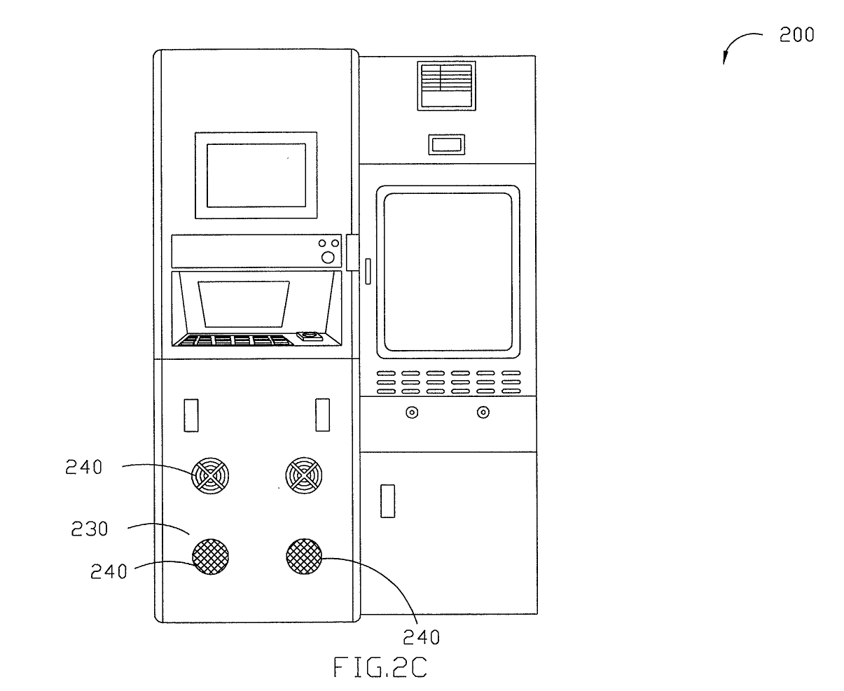

As illustrated in FIG. 2A to FIG. 2C, in the embodiment of the present invention, first of all, a surfscan apparatus 200 of TENCOR-SP1 having a room with producing heat is provided, the room with producing heat is common a circuit-board room 210 that is used to place a plurality of circuit boards 220 therein, wherein the circuit-board room 210 has a plurality of ventholes 240 and a hood plate 230 that is used to covering and closing the circuit-board room 210. The hood plate 230 has. A cooling system 250 comprises: a plurality of inhaling devices 260, such as a fan, wherein the plurality of inhaling devices 260 are installed on the hood plate 230 and connected the circuit-board room 210 with the surrounding of the surfscan apparatus 200 to convect the air between the plurality of circuit boards 220 in the circuit-board room 210, whereby heat in the circuit-board room 210 can be transmitted to the surrounding of the surfscan apparatus 200 by way of the plurality of ventholes 240. A power generator 270 is connected with the plurality of inhaling devices 260 to supply the power into the cooling system 250, wherein the power generator 270 can not affect the operation of the surfscan apparatus 200 of TENCOR-SP1.

The temperature in the circuit-board room 210 will rise to a specific temperature during operating the surfscan apparatus of TENCOR-SP1 200. At this moment, the power generator 270 is switched on to start the plurality of inhaling devices 260. Then the plurality of inhaling devices 260 work to produce a forced airflow by convecting air between the plurality of circuit boards 220 in the circuit-board room 210 and emit heat from the plurality of ventholes 240 into the environment, so as to cool down the temperature in the circuit-board room 210 and keep a temperature that is suitable for operation of the plurality of circuit boards 220 in the circuit-board room 210, whereby both the stability of the operation and life-time of the surfscan apparatus 200 of TENCOR-SP1 can be raised at the same time.

In this embodiment of the present invention, as discussed above, this invention can use a cooling system in the circuit-board room of TENCOR-SP1 to avoid over heating circuit boards in the circuit-board room, so as to increase the life-time of the circuit boards. Furthermore, this invention can also prevent the circuit boards to crash or go down. Therefore, this invention can reduce the maintainable cost of the conventional apparatus, so that the present invention can correspond to economic effect. Hence, the present invention is appropriate for deep sub-micron technology in providing semiconductor apparatus.

Of course, it is possible to apply the present invention to the surfscan apparatus of TENCOR-SP1, and also it is possible to apply the present invention to any surfscan apparatus in the semiconductor apparatus. Also, this invention can be applied to cool down the temperature by the cooling system concerning the surfscan apparatus used for increasing the life-time of the surfscan apparatus has not been developed at present. The cooling system of the present invention is the best cooling device compatible for deep sub-micro apparatus.

Obviously, many modifications and variations of the present invention are possible in light of the above teachings. It is therefore to be understood that within the scope of the appended claims, the present invention may be practiced other than as specifically described herein.

Although these specific embodiments have been illustrated and described, it will be obvious to those skilled in the art that various modifications may be made without departing from what is intended to be limited solely by the appended claims.

What is claimed is:

1. A cooling system of a surfscan apparatus, wherein said surfscan apparatus has a room with producing heat, said cooling system comprising:
a venthole, said venthole connects said room with the surrounding of said surfscan apparatus; and
a inhaling device, said inhaling device connects said room with the surrounding of said surfscan apparatus, and said inhaling device forcefully inhale air into said room with producing heat, so as to emit heat out to the surrounding of said surfscan apparatus via said venthole.

2. The system according to claim 1, wherein said room with producing heat comprises a circuit-board room.

3. The system according to claim 1, wherein said room with producing heat comprises a hood plate.

4. The system according to claim 1, wherein said inhaling device comprise a fan that is used to producing a forced airflow.

5. The system according to claim 4, wherein said fan is installed on said hood plate, so as to transmit said forced airflow via opening of said hood plate.
